(19) United States
(12) Patent Application Publication
(10) Pub. No.: US 2016/0228951 A1
(43) Pub. Date: Aug. 11, 2016

(54) PROCESS FOR PRODUCING A METAL NANOPARTICLE COMPOSITION

(71) Applicant: CIMA NANOTECH ISRAEL LTD., Caesarea (IL)

(72) Inventors: Dmitry Lekhtman, Afula (IL); Arkady Garbar, Lakeville, MN (US); Wah Chung Wong, Belfield (AU)

(21) Appl. No.: 15/021,064

(22) PCT Filed: Sep. 11, 2014
(86) PCT No.: PCT/IB14/64441

§ 371 Date: Mar. 10, 2016

Related U.S. Application Data
(60) Provisional application No. 61/876,855, filed on Sep. 12, 2013.

(51) Int. Cl. B22F 9/04; H01L 31/05; H01L 31/18; B22F 1/00; C22F 1/04

(52) U.S. Cl. CPC B22F 9/04; B22F 1/0018; C22F 1/04; H01L 31/18; H01L 31/0512; C22C 21/00

(57) ABSTRACT

A method for producing a metal nanoparticle composition including: (a) providing an alloy that includes silver and aluminum; (b) subjecting the alloy to a first thermal treatment to form a thermally treated alloy; (c) cold working the thermally treated alloy to form strips or pellets comprising the alloy; (d) subjecting the strips or pellets to a second thermal treatment at a temperature less than 440° C. to form thermally treated strips or pellets; (e) subjecting the thermally treated strips or pellets to a leaching agent effective to leach out a portion of the aluminum and form a metal nanoparticle composition comprising metal nanoparticles; and (f) washing, filtering, and then drying the metal nanoparticle composition.

### CROSS-REFERENCE TO RELATED APPLICATIONS

This application claims the benefit of U.S. Provisional Ser. No. 61/876,855, filed Sep. 12, 2013. The disclosure of the prior application is considered part of (and is incorporated by reference in) the disclosure of this application.

### TECHNICAL FIELD

This invention relates to producing metal nanoparticle compositions.

### BACKGROUND

Silver nanoparticles have found use in a number of electro-optical applications, including solar cells, displays, and the like. For example, silver nanoparticles may be incorporated into an emulsion. When the emulsion is applied to a substrate and then dried, the silver nanoparticles self-assemble to form a transparent, conductive network characterized by interconnected silver metal traces defining cells.

A number of processes for manufacturing silver nanoparticles are known. Examples include processes described in Khasin et al., U.S. Pat. No. 5,476,535; Garbar et al., U.S. Pat. No. 7,544,229; and Garbar et al., U.S. Pat. No. 8,101,005. In each of these three patents, the goal is to prepare silver nanoparticle compositions of high purity, e.g., containing at least 99% by weight silver.

### SUMMARY

A method for producing a metal nanoparticle composition is described. The method includes (a) providing an alloy comprising silver and aluminum; (b) subjecting the alloy to a first thermal treatment to form a thermally treated alloy; (c) cold working the thermally treated alloy to form strips or pellets that include the alloy; (d) subjecting the strips or pellets to a second thermal treatment at a temperature less than 440° C. to form thermally treated strips or pellets; (e) subjecting the thermally treated strips or pellets to a leaching agent effective to leach out a portion of the aluminum and form a metal nanoparticle composition that includes metal nanoparticles; and (f) washing, filtering, and then drying the metal nanoparticle composition.

As used herein, “nanoparticles” are fine particles small enough to be dispersed in a liquid to the extent they can be coated and form a uniform coating. This definition includes particles having an average particle size less than about three micrometers. For example, in some embodiments, the average particle size is less than one micrometer, and in some embodiments the particles measure less than 0.1 micrometer in at least one dimension.

In some embodiments, the temperature of the second thermal treatment is less than 400° C. For example, the temperature may range from 200 to 400° C. The temperature of the first thermal treatment may range from 350 to 500° C. The aluminum content of the alloy may range from 40 to 97% by weight. The resulting dried metal nanoparticle composition includes silver-aluminum nanoparticles, which may be present in combination with silver nanoparticles. The aluminum content of the dried metal nanoparticle composition may be greater than 1.0% by weight based upon the weight of the composition. In some embodiments, the aluminum content may be at least 5% or at least 10% by weight based upon the weight of the composition. In still other embodiments, the aluminum content may range from greater than 1.0% to 15% by weight based upon the weight of the composition.

The leaching agent may be a base or an acid. Examples of basic leaching agents include sodium hydroxide, potassium hydroxide, and combinations thereof. Examples of acidic leaching agents include acetic acid, hydrochloric acid, formic acid, sulfuric acid, hydrofluoric acid, and combinations thereof.

In some embodiments, the dried metal nanoparticle composition may be treated with a chemical reagent to form a coated composition, and then de-agglomerated. Examples of representative chemical reagents include sorbitan esters, polyoxyethylene esters, alcohols, glycerin, polyglycols, organic acids, organic acid salts, organic acid esters, thiols, phosphines, low molecular weight polymers, and combinations thereof. Examples of useful de-agglomeration methods include jet mills, mechanical dispersers, mechanical homogenizers, and ultrasonic homogenizers.

The silver-aluminum metal nanoparticle compositions may be incorporated in emulsions, dispersions, inks, or pastes, and used in the manufacture of a number of articles, including photovoltaic cells. The inclusion of aluminum in the nanoparticle composition, versus essentially pure silver, makes the compositions particularly useful in photovoltaic cell applications.

The details of one or more embodiments of the invention are set forth in the accompanying drawing and the description below. Other features, objects, and advantages of the invention will be apparent from the description and drawing, and from the claims.

### DESCRIPTION OF DRAWINGS

FIG. 1 is a scanning electron micrograph of a nanoparticle composition prepared according to Example 2.

FIG. 2 is a scanning electron micrograph of a nanoparticle composition prepared according to Example 4.

### DETAILED DESCRIPTION

Silver-aluminum metal nanoparticle compositions are prepared according to the process described in the Summary of the Invention. The initial silver-aluminum alloy composition and the temperature of the second thermal treatment are selected to create silver-aluminum nanoparticle compositions with a non-negligible amount of aluminum, e.g., on the order of greater than 1.0% by weight based upon the total weight of the nanoparticle composition. In some embodiments, the amount of aluminum is at least 5% or at least 10% by weight based upon the weight of nanoparticle composition. Typically, the amount of aluminum in the composition ranges from greater than 1.0% to 15% by weight. In general, the temperature of the first thermal treatment may range from 350 to 500° C. The temperature of the second thermal treatment is less than 440° C., and may be in the range of 200-400° C.

The term “cold working” refers to work or force provided on the article. Representative examples include pressing, compressing, squashing, mashing, pulverizing, grinding, milling, and combinations thereof. Cold working creates strips or pellets having a high surface area to mass ratio that facilitates the subsequent leaching treatment. The strips may have a thickness on the order of about 0.1 to 2 mm (e.g., 0.3 to 1 mm).

The nanoparticle compositions may be incorporated in emulsions or dispersions. For example, the nanoparticle compositions may be combined with glass frit particles in a liquid emulsion, which is then used to form a transparent conductive layer that self-assembles to form a series of interconnected traces (e.g., lines) defining cells following application to the back side of a passivated semiconductor substrate as described in commonly owned Wong et al., “Method of Manufacturing Photovoltaic Cells Having a Backside Passivation Layer,” U.S. Ser. No. 61/820,852 filed May 8, 2013, which is incorporated by reference in its entirety.

The emulsion includes a continuous liquid phase and a dispersed liquid phase that is immiscible with the continuous liquid phase and forms dispersed domains within the continuous liquid phase. In some implementations, the continuous phase evaporates more quickly than the dispersed phase. One example of a suitable emulsion is a water-in-oil emulsion, where water is the dispersed liquid phase and the oil provides the continuous phase. The emulsion can also be in the form of an oil-in-water emulsion, where oil provides the dispersed liquid phase and water provides the continuous phase.

The continuous phase can include an organic solvent. Suitable organic solvents may include petroleum ether, hexanes, heptanes, toluene, benzene, dichloroethane, trichloroethylene, chloroform, dichloromethane, nitromethane, dibromomethane, cyclopentanone, cyclohexanone or any mixture thereof. Preferably, the solvent or solvents used in this continuous phase are characterized by higher volatility than that of the dispersed phase, e.g., the water phase.

Suitable materials for the dispersed liquid phase can include water and/or water miscible solvents such as methanol, ethanol, ethylene glycol, propylene glycol, glycerol, dimethyl formamide, dimethyl acetamide, acetonitrile, dimethyl sulfoxide, N-methyl pyrrolidone.

The emulsion may also contain at least one emulsifying agent, binder or any mixture thereof. Suitable emulsifying agents can include non-ionic and ionic compounds, such as the commercially available surfactants SPAN®-20 (Sigma-Aldrich Co., St. Louis, Mo.), SPAN®-40, SPAN®-60, SPAN®-80 (Sigma-Aldrich Co., St. Louis, Mo.), glyceryl monooleate, sodium dodecylsulfate, or any combination thereof. Examples of suitable binders include modified cellulose, such as ethyl cellulose with a molecular weight of about 100,000 to about 200,000, and modified urea, e.g., the commercially available BYK®-410, BYK®-411, and BYK®-420 resins produced by BYK-Chemie GmbH (Wesel, Germany).

Other additives may also be present in the oil phase and/or the water phase of the emulsion formulation. For example, additives can include, but are not limited to, reactive or non-reactive diluents, oxygen scavengers, hard coat components, inhibitors, stabilizers, colorants, pigments, IR absorbers, surfactants, wetting agents, leveling agents, flow control agents, thixotropic or other rheology modifiers, slip agents, dispersion aids, defoamers, humectants, and corrosion inhibitors.

The glass frit particles burn through the passivation layer. A variety of glass frit particles are available and may include lead or be lead-free. Glass frit may include metal oxides such as lead, zinc, boron, bismuth, and tellurium. Particle sizes of glass frit may range from nano-sized to micron-sized, e.g., up to 5 μm or up to 10 μm. Preferably, the glass frit particle size is consistent with the self-assembly process such that the glass frit particles self-assemble into a network. In the case of larger glass frit particles, methods for reducing particle sizes may be employed, such as grinding or milling, prior to combining the particles with the emulsion. Glass frit particles may be present in the emulsion at concentrations ranging from 0.1 wt. % to 10 wt. %.

The composition can be coated onto the semiconductor substrate using bar spreading, immersing, spin coating, dipping, slot die coating, gravure coating, flexographic plate printing, spray coating, or any other suitable techniques. In some implementations, the homogenized coating composition is coated onto the semiconductor substrate until reaching a thickness of about 1 to 200 microns, e.g., 5 to 200 microns.

Prior to coating the emulsion on the substrate, the substrate can be pre-treated, e.g., with a coating, to improve certain properties. For example, the substrate may be provided with a primer layer to improve adhesion between the substrate and the coated emulsion.

After applying the emulsion to the semiconductor substrate; the liquid portion of the emulsion is evaporated, with or without the application of heat. When the liquid is removed from the emulsion, the nanoparticles self-assemble into a network-like pattern of traces defining cells that are transparent to light. The self-assembled network preferably provides low areal coverage (i.e. the area or percentage of the area of the substrate covered by the network) to maximize the area covered by the passivation layer, including areal coverages of less than 10% or even less than 5%. Areal coverage is determined by a combination of cell sizes (i.e. the openings in the network) and line widths (i.e. the width of the network lines). Self-assembled networks may provide line widths that are narrower than typical printing processes, e.g. less than 10 μm or even less than 5 μm, thus providing lower areal coverages.

In some implementations, the cells are randomly shaped. In other implementations, the process is conducted to create cells having a regular pattern. An example of such a process is described in WO 2012/170684 entitled “Process for Producing Patterned Coatings,” filed Jun. 10, 2011, which is assigned to the same assignee as the present application and hereby incorporated by reference in its entirety. According to this process, the composition is coated on a surface of the substrate (e.g., a semiconductor substrate) and dried to remove the liquid carrier while applying an outside force during the coating and/or drying to cause selective growth of the dispersed domains, relative to the continuous phase, in selected regions of the substrate. Application of the outside force causes the non-volatile component (the nanoparticles) to self-assemble and form a coating in the form of a pattern that includes traces defining cells having a regular spacing (for instance, a regular center-to-center spacing), determined by the configuration of the outside force. Application of the outside force may be accomplished, for example, by depositing the composition on the substrate surface and then passing a Mayer rod over the composition. Alternatively, the composition can be applied using a gravure cylinder. In another implementation, the composition may be deposited on the substrate surface, after which a lithographic mask is placed over the composition. In the case of the mask, as the composition dries, the mask forces the composition to adopt a pattern corresponding to the pattern of the mask.

In each case, it is the outside force that governs the pattern (specifically, the center-to-center spacing between cells in the dried coating). However, the width of the traces defining the cells is not directly controlled by of the outside force. Rather, the properties of the emulsion and drying conditions are the primary determinant of the trace width. In this fashion, lines substantially narrower than the outside force can be readily manufactured, without requiring the difficulty and expense of developing processes, masters, and materials having very fine linewidth. Fine linewidth can be generated with the emulsion and drying process. However, the outside force can be used (easily and inexpensively) to control the size, spacing, and orientation of the cells of the network.

Following liquid removal and formation of the self-assembled layer, the layer may be sintered using known techniques such as thermal, mechanical, radiation, or chemical sintering, or combinations thereof.

Following liquid removal, formation of the self-assembled layer, and any optional sintering treatments, an electrode layer may be deposited, e.g., screen printed with conductive pastes or inks. Metallic conductive pastes include aluminum or silver pastes. Electrodes may be full-coverage (e.g. on the back side of the solar cell) or may be partial-coverage to allow light to pass through the electrode (e.g., transparent electrodes on the front side of the solar cell). In the case of full-coverage electrodes on the passivated back side, it is preferable that the metallic paste does not contain burn-through components such as glass frit. In the case of bifacial solar cells, partial-coverage electrodes may be provided on both surfaces of the cell to allow light penetration from either side.

After electrode deposition, the article is fired or co-fired (in e.g. a belt furnace) at moderately high temperatures to accomplish one or more of the following steps: baking off of organic materials (e.g. binders or solvents), firing-through, sintering, annealing, and alloying to provide good ohmic contact between the layers. Temperatures may be ramped or stepped up to the peak temperatures (e.g. 700-900 deg. C.). Peak temperatures are typically held for brief periods between a few seconds and a minute.

### EXAMPLES

### Glossary

| Component | Function | Chemical description | Source |
|---|---|---|---|
| BYK-410 | Liquid | Solution of a modified urea | BYK USA, |
| | rheology | | Wallingford, |
| | additive | | CT |
| BYK-106 | Wetting | Salt of a polymer with acidic | BYK USA |
| | and | groups | |
| | dispersing | | |
| | additive | | |
| Span 60 | Nonionic | Sorbitan monostearate | Sigma- |
| | surfactant | | Aldnch, St. |
| | | | Louis, MO |
| RS 610 | Anionic | Polyoxyethylene tridecyl ether | Solvay- |
| | surfactant | phosphate, available as | Rhodia, |
| | | Rhodafac 610 | Cranbury, |
| | | | NJ |
| BYK-348 | Silicone | Polyether modified | BYK USA |
| | surfactant | polydimethylsiloxane | |
| Disperbyk- | Wetting | Structured acrylate copolymer | BYK USA |
| 2025 | and | | |
| | dispersing | | |
| | additive | | |
| Cymel 1141 | Crosslinker | Highly alkylated mixed ether | Cytec |
| | | carboxylated melamine resin | Industries, |
| | | | Woodland |
| | | | Park, NJ |
| VIOX 0981 | Glass frit | Glass particles having SiO₂, | Ceradyne |
| | for burn- | PbO, and B₂O₃, particle size | VIOX, |
| | through | about 0.5 um | Seattle, WA |
| Synperonic | Nonionic | Polyethylene glycol | Fluka, |
| NP-30 | surfactant | nonylphenyl ether | Sigma- |
| | | | Aldrich |
| | Emulsifier | Poly[dimethylsiloxane-co-[3- | Sigma- |
| | | (2-(2-hydroxyethoxy)eth- | Aldrich |
| | | oxy)propyl]methyl- | |
| | | siloxane], viscosity 75 cSt | |

### Example 1

840 grams of aluminum pellets (99.99% pure, nominal diameter 0.95 cm, C-KOE Metals L.P., Dallas, Tex.) were weighed into a ceramic crucible having a graphite interior. The crucible was placed into an induction furnace at 60% power (Opdel FS10 Induction Furnace, Opticom, Italy) under an Argon flow (about 1 L/min. Argon) until all of the aluminum had melted, about 6-7 min. 360 grams of silver pellets (silver granules, 99.99% purity, Umicore N.V., Belgium) were added to the melted aluminum inside the furnace and stirred several times using a graphite stirrer until the silver had melted, about 3-4 min., to form a homogeneous melt. The melt was immediately cast into a steel mold to form an ingot 250×115×15 mm.

First heat treatment: The ingot was placed into an electric furnace (Series K750, Heraeus GmbH, Germany) set at 400 deg. C. and held at that temperature for 2 hr. The furnace was turned off and the ingot was allowed to slowly cool before removal.

Using a rolling machine (BW-250, Carl Wezel KG, Germany), the ingot was passed through the rollers repeatedly, slowly decreasing the thickness of the ingot to form 1 mm strips. The rolled strips were cut into shorter lengths for further heat treatment.

Second heat treatment: The electric furnace was set at 200 deg. C. and the rolled strips were placed into the furnace and held at 200 deg. C. for 4 hr. The heat treated strips were removed from the furnace and quickly quenched in deionized water at 25 deg. C. or lower for 10-20 min.

On the same day as the second heat treatment, the strips were first surface-cleaned using 5% (wt/wt) sodium hydroxide in deionized water by immersing the strip until bubbles formed on the surface, about 2-3 min. For both the surface cleaning and the leaching, about 2 liters of NaOH solution was used for approximately 62 g. strips. The strips were immediately removed and rinsed with deionized water. Next, the strips were leached using 25% (wt/wt) sodium hydroxide in deionized water for 8-10 hrs. at approximately room temperature (due to the exothermic nature of the process, the liquid temperature increases throughout the process) to form a black powder. The leaching solution was decanted and replaced with deionized water repeatedly until the pH was approximately neutral. The black powder was then dried in a 40 deg. C. oven for about 24 hrs. The dried powder was then sieved through a 500 um sieve to form the final nanoparticle composition.

The aluminum content of the nanoparticle composition, as determined by ICP, was 14.50% by wt.

### Example 2

The procedure of Example 1 was repeated using a second heat treatment temperature of 250 deg. C. The aluminum content as determined by ICP was 13.70% by wt.

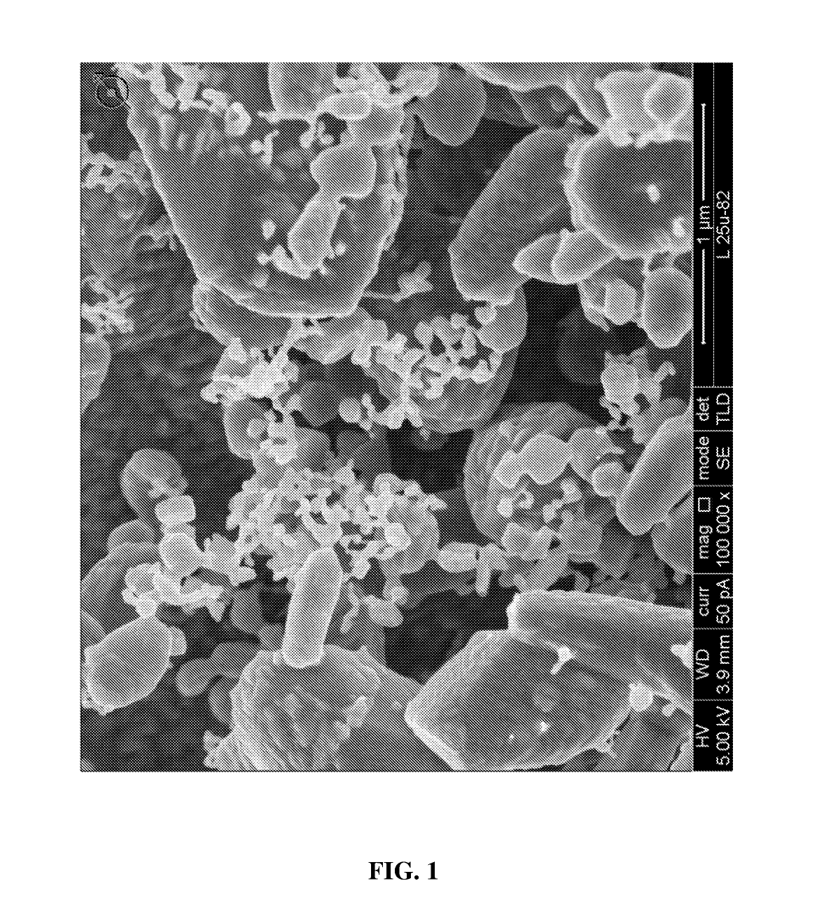

FIG. 1 is a scanning electron micrograph of the resulting powder, showing a blend of particles produced by the process. The larger particles, e.g., 1-2 μm, are silver-aluminum particles, while the smaller particles, e.g. 50-100 nm, are composed of 99+% silver.

Energy dispersive x-ray spectroscopy (EDS, EDAX, Inc., Mahwah, N.J.) was used to analyze the larger particles in the resulting powder. Three of the larger particles in the blend were analyzed by focusing in on individual particles. Normalizing the results to exclude carbon and oxygen, thus only including aluminum and silver in the calculation, the three large particles had 13.31, 13.82, and 13.16% aluminum by wt.

Although the EDS size resolution was incapable of providing data from individual smaller particles, the focus was moved to areas of the resulting powder having groups of smaller particles. These three areas had 11.87, 8.92, and 12.96% aluminum by wt., suggesting that the smaller particles were higher in silver content.

### Example 3

The procedure of Example 1 was repeated using a second heat treatment temperature of 400 deg. C. The aluminum content as determined by ICP was 11.63% by wt.

### Example 4 (Comparative)

The procedure of Example 1 was repeated using a second heat treatment temperature of 500 deg. C. The aluminum content as determined by ICP was 0.35% by wt.

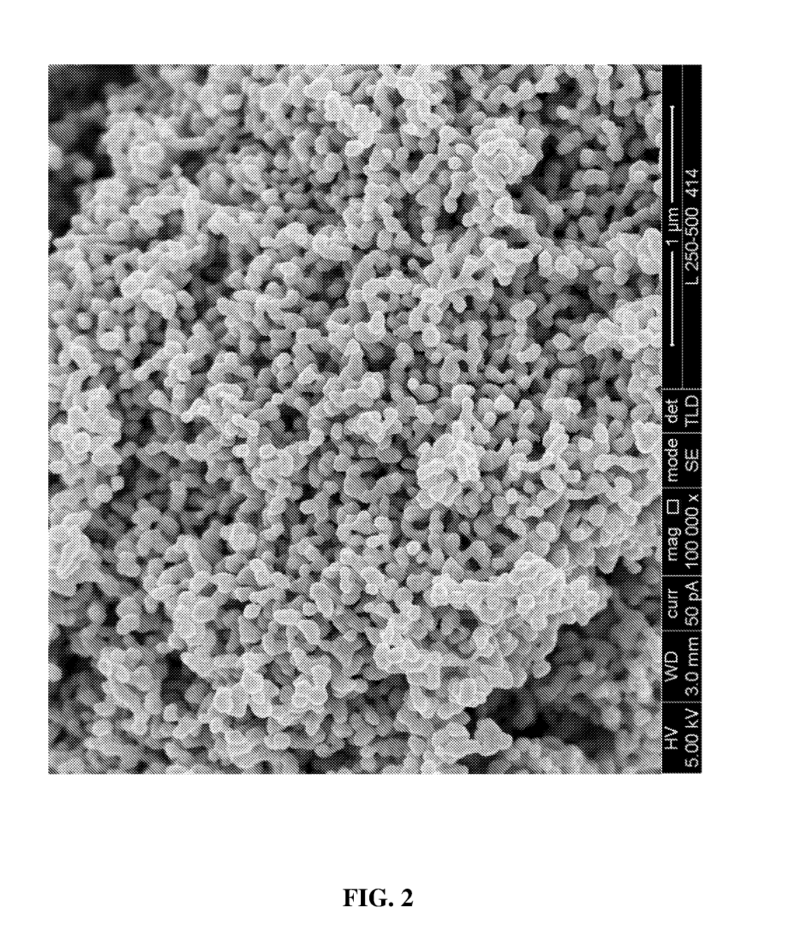

FIG. 2 is a scanning electron micrograph of the resulting powder, showing that primarily smaller particles were produced by the process using a 500 deg. C. second thermal treatment.

### Example 5

The procedure of Example 1 was repeated using a second heat treatment temperature of 220 deg. C. The aluminum content as determined by ICP was 13.5% by wt. These nanoparticles were used in the emulsion of Example 6.

### Example 6

Multicrystalline silicon wafers (200 um thickness, 156×156 mm) were obtained from Tianwei Corporation, China. The front sides of the wafers had been surface textured, phosphorus-diffused to form the n-layer (having a sheet resistance of 70 Ohms/square), and coated with an 80 nm antireflection coating of silicon nitride. The back sides of the wafers had been coated (plasma enhanced chemical vapor deposition) with a 40 nm layer of silicon oxynitride followed by a 40 nm layer of silicon nitride.

The back side of the wafers were primed using an approximately 8 um wet thickness coating of a primer solution (0.6 wt. % Synperonic NP-30 and 0.3 wt. % Poly[dimethylsiloxane-co-[3-(2-(2-hydroxyethoxy)ethoxy)propyl]methylsiloxane] in 99.1 wt. % acetone). The primer was applied with a Mayer rod and allowed to air dry.

An emulsion was prepared by first mixing the components shown in Table 5 and sonicating until uniform to form Solution A. Next, 23.5 grams of a BYK-348 solution (0.04 wt % in DI water) was added to Solution A and sonicated until uniform to form Solution B. Finally, 0.17 g of BYK-106 and 0.32 g of Disperbyk-2025 solution (0.1 wt. % in toluene) were added to the solution B and mixed to form the final emulsion.

Next, the primed back side of the wafer was coated with the emulsion described above. The emulsion was coated using a Mayer rod to a wet coating thickness of 20-30 um, and the coating was allowed to dry, during which time the network self-assembled. The coated wafers were first placed in a 50 deg. C. oven for about a minute, then placed in a 150 deg. C. oven for 20 minutes.

Next, back side bus bars were screen printed using silver paste and a full coverage aluminum electrode was screen printed using aluminum paste. The front side electrode (H-grid) was printed using silver paste.

The wafer was next baked and co-fired using a 300-350 deg. C. baking step, a 450-600 deg. C. organic burn-off and alloying step, a 600-700 deg. C. pre-heating step, and an 800-900 deg. C. fire-through step, the final temperature being briefly maintained for less than 60 sec. Finally, a laser edge-isolation etch was done.

TABLE 5
Example 6 emulsion composition

| Component | Weight (grams) |
|---|---|
| VIOX 0981 | 0.13 |
| RS 610 | 0.0026 |
| Toluene | 20.5 |
| P-xylene | 4.0 |
| Cyclohexanone | 2.3 |
| BYK-410 | 0.18 |
| Span 60 | 0.08 |
| Cymel 1141 | 0.06 |
| BYK-106 | 0.06 |
| Silver-aluminum nanoparticles of | 5.2 |
| Example 5 | |

The sample was tested with standard solar cell test methods using a solar simulator, the results are shown in Table 6. The results demonstrate that the emulsion with silver-aluminum nanoparticles was capable of burning through the passivation layer, thus establishing ohmic contact.

TABLE 6
Example 6 test results

| | | Short | | | | |
|---|---|---|---|---|---|---|
| | Open Circuit | Circuit | Series | Shunt | Fill | |
| | Voltage | Current | Resistance | Resistance | Factor | Efficiency |
| Replicate | (Voc, Volts) | (Isc, amps) | (Rs, Ohms) | (Rsh, Ohms) | (FF, %) | (%) |
| 1 | 0.6040 | 8.2284 | 0.0038 | 19.9301 | 77.0451 | 16.7406 |
| 2 | 0.6088 | 8.4143 | 0.0097 | 17.7279 | 68.6641 | 15.3782 |
| 3 | 0.6066 | 8.4003 | 0.0077 | 48.5036 | 71.1658 | 15.8534 |
| 4 | 0.6086 | 8.3374 | 0.0078 | 29.3215 | 71.3658 | 15.8315 |
| 5 | 0.6072 | 8.3822 | 0.0064 | 25.6555 | 72.9429 | 16.2292 |

A number of embodiments of the invention have been described. Nevertheless, it will be understood that various modifications may be made without departing from the spirit and scope of the invention. Accordingly, other embodiments are within the scope of the following claims.

What is claimed is:

1. A method for producing a metal nanoparticle composition comprising:
(a) providing an alloy comprising silver and aluminum;
(b) subjecting the alloy to a first thermal treatment to form a thermally treated alloy;
(c) cold working the thermally treated alloy to form strips or pellets comprising the alloy;
(d) subjecting the strips or pellets to a second thermal treatment at a temperature less than 440° C. to form thermally treated strips or pellets;
(e) subjecting the thermally treated strips or pellets to a leaching agent effective to leach out a portion of the aluminum and form a metal nanoparticle composition comprising metal nanoparticles; and
(f) washing, filtering, and then drying the metal nanoparticle composition.

2. A method according to claim 1 comprising subjecting the strips or pellets to a second thermal treatment at a temperature less than 400° C.

3. A method according to claim 1 comprising subjecting the strips or pellets to a second thermal treatment at a temperature between 200° C. and 400° C.

4. A method according to claim 1 wherein the alloy includes between 40 and 97% by weight aluminum.

5. A method according to claim 1 wherein the dried metal nanoparticle composition comprises silver-aluminum nanoparticles.

6. A method according to claim 5 wherein the dried metal nanoparticle composition comprises silver nanoparticles and silver-aluminum nanoparticles.

7. A method according to claim 5 wherein the dried metal nanoparticle composition has an aluminum content of greater than 1.0% by weight based upon the weight of the composition.

8. A method according to claim 5 wherein the dried metal nanoparticle composition has an aluminum content of at least 5% by weight based upon the weight of the composition.

9. A method according to claim 5 wherein the dried metal nanoparticle composition has an aluminum content of at least 10% by weight based upon the weight of the composition.

10. A method according to claim 5 wherein the dried metal nanoparticle composition has an aluminum content of between greater than 1.0% and 15% by weight based upon the weight of the composition.

11. A method according to claim 1 wherein the leaching agent is selected from the group consisting of sodium hydroxide, potassium hydroxide, and combinations thereof.

12. A method according to claim 1 wherein the leaching agent is selected from the group consisting of acetic acid, hydrochloric acid, formic acid, sulfuric acid, hydrofluoric acid, and combinations thereof.

13. A method according to claim 1 further comprising treating the dried metal nanoparticle composition with a chemical reagent to form a coated metal nanoparticle composition, and then de-agglomerating the coated metal nanoparticle composition.

14. A metal nanoparticle composition prepared according to the method of claim 1.

15. A metal nanoparticle composition comprising silver nanoparticles and silver-aluminum nanoparticles in which the aluminum content of the composition is greater than 1.0% by weight based upon the weight of the composition.

16. A metal nanoparticle composition according to claim 15 wherein the aluminum content of the composition is at least 5% by weight based upon the weight of the composition.

17. A metal nanoparticle composition according to claim 15 wherein the aluminum content of the composition is at least 10% by weight based upon the weight of the composition.

18. A metal nanoparticle composition according to claim 15 wherein the aluminum content of the composition is between greater than 1.0% and 15% by weight based upon the weight of the composition.

19. A process for making a photovoltaic cell comprising:
(a) providing a semiconducting substrate having a back side passivation layer;
(b) coating a self-assembling emulsion comprising glass frit particles and the metal nanoparticle composition of claim 15 onto the back side passivation layer;
(c) allowing the emulsion to self-assemble into a network of traces that define cells;
(d) forming an electrode over the network to create a precursor cell; and
(e) firing the precursor cell to cause the network to burn through the passivation layer and establish electrical contact between the semiconducting substrate and the electrode.
